(19) United States
(12) Patent Application Publication
(10) Pub. No.: US 2014/0077297 A1
(43) Pub. Date: Mar. 20, 2014

(54) THIN FILM TRANSISTOR AND METHOD OF FABRICATING THE SAME

(71) Applicant: Electronics and Telecommunications Research Institute, (US)

(72) Inventors: Jae Bon KOO, Daejeon (KR); Soon-Won JUNG, Daejeon (KR); Bock Soon NA, Daejeon (KR); Chan Woo PARK, Daejeon (KR); Sang Chul LIM, Daejeon (KR); Ji-Young OH, Deajeon (KR); Hye Yong CHU, Daejeon (KR)

(73) Assignee: Electronics and Telecommunications Research Institute, Daejeon (KR)

(21) Appl. No.: 13/772,236

(22) Filed: Feb. 20, 2013

(30) Foreign Application Priority Data
Sep. 20, 2012 (KR) 10-2012-0104549

(51) Int. Cl. H01L 29/786; H01L 29/66

(52) U.S. Cl. CPC H01L 29/78603; H01L 29/66742
USPC 257/347; 438/151

(57) ABSTRACT

Provided is a thin film transistor. The thin film transistor according to an embodiment of the present invention may include a source electrode and a drain electrode buried in a first flexible substrate, a semiconductor layer disposed on the first flexible substrate to be positioned between the source electrode and the drain electrode, a gate insulating layer completely cover the semiconductor layer, and a gate electrode facing the semiconductor layer on the gate insulating layer.

### CROSS-REFERENCE TO RELATED APPLICATIONS

This U.S. non-provisional patent application claims priority under 35 U.S.C. §119 of Korean Patent Application No. 10-2012-0104549, filed on Sep. 20, 2012, the entire contents of which are hereby incorporated by reference.

### BACKGROUND

The present invention disclosed herein relates to a thin film transistor and a method of fabricating the same, and more particularly, to a thin film transistor having improved stretchability and bending characteristics, and a method of fabricating the same.

Stretchable electronic devices are advanced electronic devices which may maintain electrical functions, even in the case that substrates are expanded or contracted when external stress is applied thereto. A technique for stretchable electronic circuits, differing from typical flexible devices only having a bendable function, has applicability in various fields, such as sensor skin for robots, wearable communication devices, implantable or wearable biodevices, or advanced displays.

A technique of securing stretchability of a device by forming wrinkles on a substrate having circuits formed thereon, a technique of using a stretchable conductive organic material having conductivity instead of metal interconnections, or a technique of patterning metal interconnections in the form of stretchable two-dimensional planar spring may be required in order to realize stretchable electronic devices.

### SUMMARY

The present invention provides a thin film transistor having more improved reliability.

The present invention also provides a method of fabricating a thin film transistor having more improved reliability.

The object of the present invention is not limited to the aforesaid, but other objects not described herein will be clearly understood by those skilled in the art from descriptions below.

Embodiments of the present invention provide thin film transistors including: a source electrode and a drain electrode buried in a first flexible substrate; a semiconductor layer disposed on the first flexible substrate to be positioned between the source electrode and the drain electrode; a gate insulating layer completely cover the semiconductor layer; and a gate electrode facing the semiconductor layer on the gate insulating layer.

In some embodiments, the first flexible substrate may be formed of polydimethylsiloxane (PDMS) or polyurethane.

In other embodiments, a top surface of the first flexible substrate may be coplanar with a top surface of the source electrode and a top surface of the drain electrode.

In still other embodiments, the thin film transistor may further include a second flexible substrate covering the gate electrode on the gate insulating layer.

In even other embodiments, the first flexible substrate may be thicker than the second flexible substrate.

In other embodiments of the present invention, thin film transistors including: a gate electrode buried in a flexible substrate; a gate insulating layer formed on the flexible substrate; a source electrode and a drain electrode disposed to be positioned at both sides of the gate electrode on the gate insulating layer; and a semiconductor layer disposed between the source electrode and the drain electrode.

In some embodiments, the semiconductor layer may extend to top surfaces of the source electrode and the drain electrode.

In other embodiments, the source electrode and the drain electrode may be spaced apart to each other and may extend to a top surface of the semiconductor layer.

In still other embodiments of the present invention, methods of fabricating a thin film transistor including: sequentially forming a sacrificial layer on a substrate; forming one or more metal patterns on the sacrificial layer; forming a flexible substrate on the sacrificial layer to cover the metal pattern; and removing the sacrificial layer to form the flexible substrate having the metal pattern buried therein.

In some embodiments, the forming of the metal pattern may include: forming a photoresist pattern on the sacrificial layer; forming a metal layer on the photoresist pattern; and removing the photoresist pattern by using a lift-off method.

In other embodiments, the forming of the flexible substrate may include: coating the sacrificial layer with a soft material solution to completely cover the metal pattern; removing bubbles included in the soft material solution in a vacuum state; and curing the soft material solution.

In still other embodiments, the soft material solution may be polydimethylsiloxane (PDMS) or polyurethane.

In even other embodiments, the insulating layer may be removed by performing a wet etching or laser lift-off process.

In yet other embodiments, the metal pattern may be a gate electrode.

In further embodiments, the method may further include: forming a gate insulating layer on the flexible substrate having one surface of the gate electrode exposed thereon; forming a source electrode and a drain electrode on the gate insulating layer to be disposed at both sides of the gate electrode; and forming a semiconductor layer between the source electrode and the drain electrode.

In still further embodiments, the metal patterns may be the source electrode and the drain electrode.

In even further embodiments, the method may further include: forming a semiconductor layer on the flexible substrate having one surface of the source electrode and the drain electrode exposed thereon; forming a gate insulating layer on the flexible substrate to be disposed between the source electrode and the drain electrode; and forming a gate electrode facing the semiconductor layer on the gate insulating layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a thin film transistor according to an embodiment of the present invention;

FIGS. 2A through 2F are cross-sectional views illustrating a method of fabricating the thin film transistor according to the embodiment of the present invention;

FIG. 3 is a cross-sectional view illustrating a thin film transistor according to another embodiment of the present invention;

FIG. 4 is a cross-sectional view illustrating a modified example of the thin film transistor in FIG. 3 according to the another embodiment of the present invention;

FIGS. 5A through 5F are cross-sectional views illustrating a method of fabricating the thin film transistor according to the another embodiment of the present invention;

FIG. 6 is a cross-sectional view illustrating a thin film transistor according to another embodiment of the present invention; and

FIG. 7 is a cross-sectional view illustrating a thin film transistor according to another embodiment of the present invention.

### DETAILED DESCRIPTION OF THE EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. In the drawings, like reference numerals refer to like elements throughout.

In the following description, the technical terms are used only for explaining a specific exemplary embodiment while not limiting the present invention. The terms of a singular form may include plural forms unless referred to the contrary. The meaning of “comprises” and/or “comprising” specifies a property, a region, a fixed number, a step, a process, an element and/or a component but does not exclude other properties, regions, fixed numbers, steps, processes, elements and/or components.

Additionally, the embodiment in the detailed description will be described with sectional views and/or plan views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a semiconductor package region. Thus, this should not be construed as limited to the scope of the present invention.

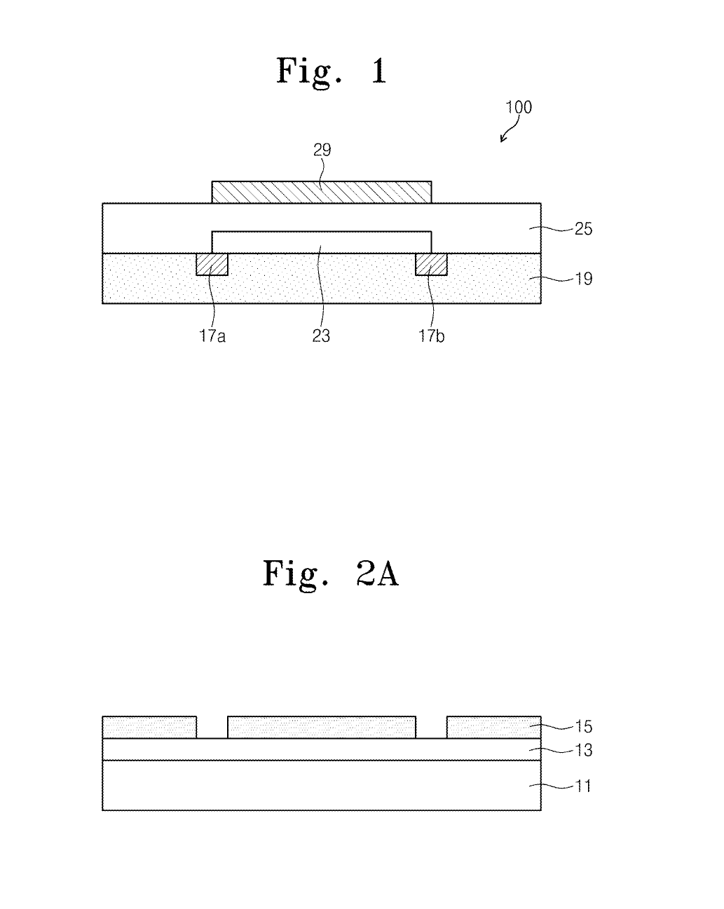

FIG. 1 is a cross-sectional view illustrating a thin film transistor according to an embodiment of the present invention.

Referring to FIG. 1, in a thin film transistor 100, a source electrode 17a and a drain electrode 17b are buried in a flexible substrate 19. A semiconductor layer 23 is disposed on the flexible substrate 19. A gate insulating layer 25 is disposed on the flexible substrate 19 to cover the semiconductor layer 23. A gate electrode 29 is disposed on the gate insulating layer 25.

The flexible substrate 19 may be a bendable or deformable polymer substrate. For example, the flexible substrate 19 may be formed of polydimethylsiloxane (PDMS) or polyurethane.

The source electrode 17a and the drain electrode 17b may be spaced apart from each other and may be buried in the flexible substrate 19. Top surfaces of the flexible substrate 19, the source electrode 17a and the drain electrode 17b may be coplanar. For example, the source electrode 17a and the drain electrode 17b may be formed of a metallic material such as tungsten (W), copper (Cu), aluminum (Al), chromium (Cr), molybdenum (Mo), silver (Ag), or gold (Au).

The semiconductor layer 23 may be disposed to be positioned between the source electrode 17a and the drain electrode 17b on the flexible substrate 19. The semiconductor layer 23 may be disposed on the flexible substrate 19 to cover portions of the top surfaces of the source electrode 17a and the drain electrode 17b. The semiconductor layer 23 may be an organic semiconductor layer, a silicon semiconductor layer, or an oxide semiconductor layer. A lower surface of the semiconductor layer 23 adjacent to the source electrode 17a and the drain electrode 17b may be a channel region in which charges may be transferred between the source electrode 17a and the drain electrode 17b.

The gate insulating layer 25 may be disposed on the flexible substrate 19 to completely cover the semiconductor layer 23. The gate insulating layer 25 may be formed of an organic layer (e.g., parylene) or an inorganic layer (e.g., silicon oxide layer (SiO₂) or silicon nitride layer (SiNₓ)).

The gate electrode 29 may be formed on the gate insulating layer 25 so as to be disposed on the same position as that of the semiconductor layer 23. Voltage applied to the gate electrode 29 may control an amount of current flowing between the source electrode 17a and the drain electrode 17b. The gate electrode 29 may be formed of polysilicon or a metallic material.

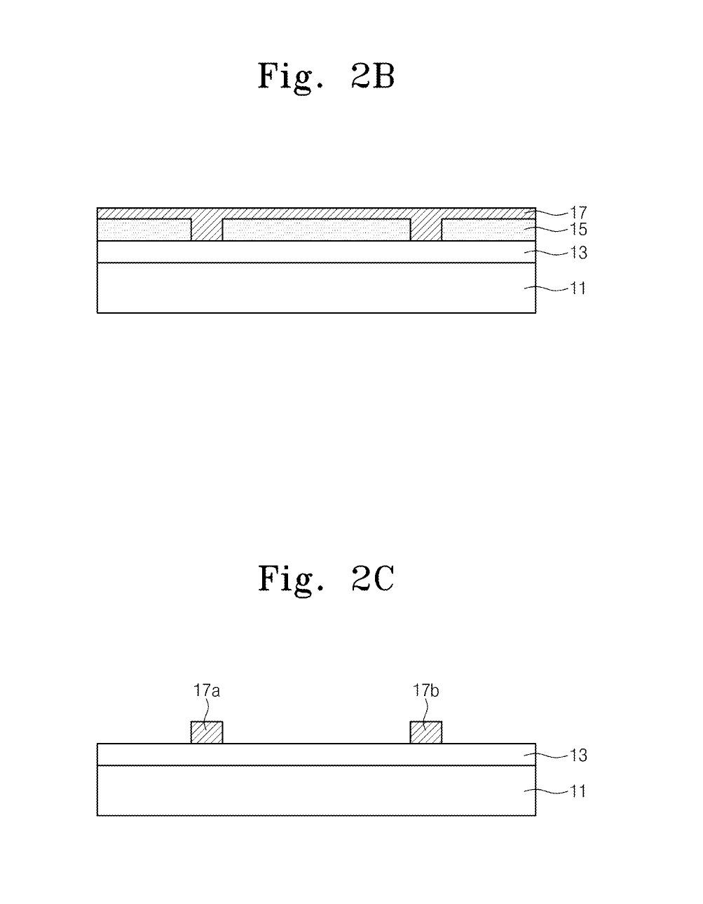

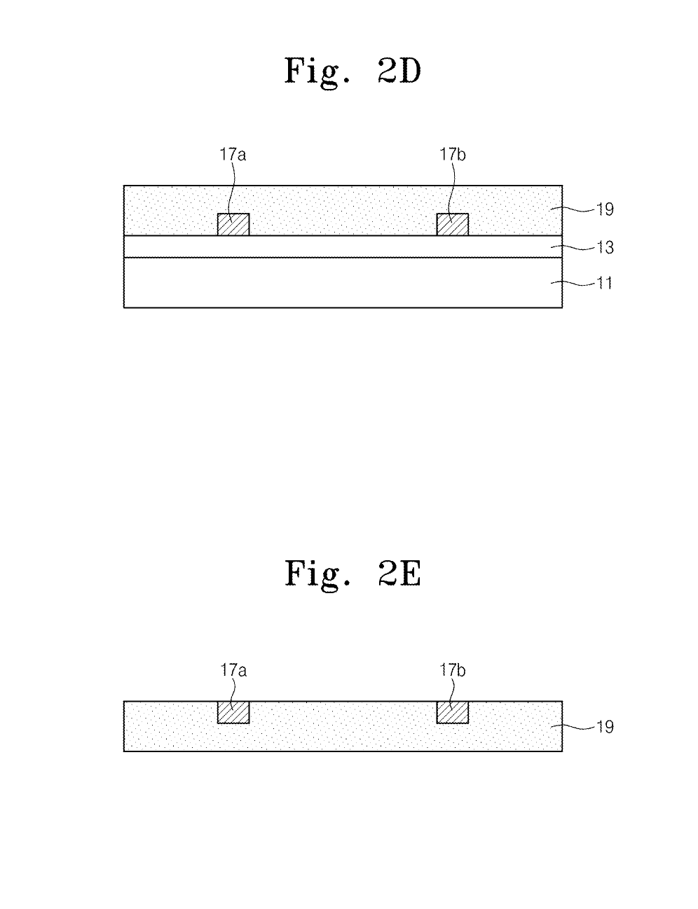

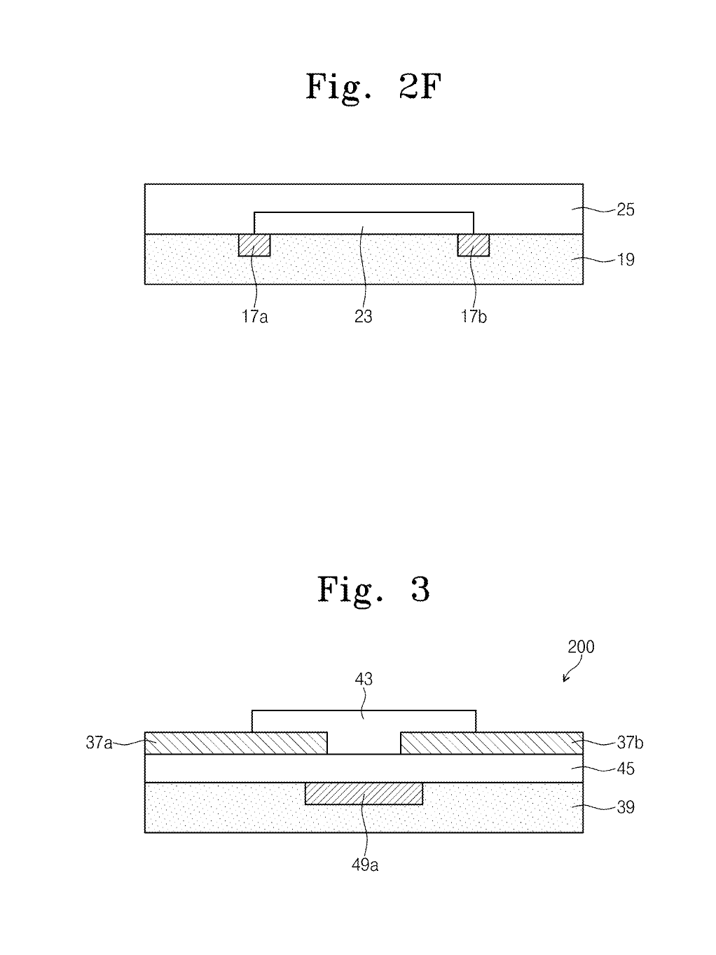

FIGS. 2A through 2F are cross-sectional views illustrating a method of fabricating the thin film transistor according to the embodiment of the present invention.

Referring to FIG. 2A, a substrate 11 is prepared, and a sacrificial layer 13 and a photoresist pattern 15 are formed on the substrate 11.

The substrate 11 may be a glass substrate, a silicon substrate, or a plastic substrate. Since the substrate 11 is removed during a subsequent process, the substrate 11 is not limited to a material.

The sacrificial layer 13 may be formed on the substrate 11 by performing chemical vapor deposition, physical vapor deposition, or atomic layer deposition. The sacrificial layer 13 may be a silicon oxide layer (SiO₂), a silicon nitride layer (SiNₓ), an aluminum oxide layer (Al₂O₃), or an organic layer such as a photoresist layer. In the case that the substrate 11 is the silicon substrate, the silicon oxide layer (SiO₂) may be formed by natural oxidation of a top surface of the silicon substrate.

The photoresist pattern 15 may be formed on the sacrificial layer 13 by performing a photolithography process. Specifically, a photoresist layer (not shown) is formed on the sacrificial layer 13 and a photomask pattern (not shown) is then used to etch the photoresist layer exposed through the photomask pattern, and thus, the photoresist pattern 15 may be formed. The photoresist pattern 15 may be formed to expose a top surface of the sacrificial layer 13. The top surface of the sacrificial layer 13 is exposed through two regions of the photoresist pattern 15 and the two regions may be regions in which source/drain electrodes are formed in a subsequent process.

Referring to FIG. 2B, an electrode layer 17 may be formed on the photoresist pattern 15.

The electrode layer 17 may be formed on the photoresist pattern 15 by chemical vapor deposition, physical vapor deposition, atomic layer deposition, or thermal evaporation to cover the top surface of the sacrificial layer 13. The electrode layer 17 may be formed of a metallic material such as W, Cu, Al, Cr, Mo, Ag, or Au.

Referring to FIG. 2C, a source electrode 17a and a drain electrode 17b may be formed on the sacrificial layer 13 by removing the photoresist pattern 15.

Specifically, the photoresist pattern 15 may be removed by performing wet etching by using sulfuric acid (H₂SO₄) and hydrogen peroxide (H₂O₂) as an etching solution. A portion of the electrode layer 17 formed above the photoresist pattern 15 may be etched at the same time when the photoresist pattern 15 is etched. The reason for this is that since a thickness of the photoresist pattern 15 is about a few hundred micrometers and a thickness of the metal layer 17 is about a few micrometers, a portion of the metal layer 17 unprotected by the photoresist pattern 15 may be removed by the etching solution. Alternatively, a portion of the metal layer 17 protected by the photoresist pattern 15 may remain on the sacrificial layer 13 to form the source electrode 17a and the drain electrode 17b. Since the source electrode 17a and the drain electrode 17b are not patterned by a photolithography process but formed according to a width of the photoresist pattern 15, the source electrode 17a and the drain electrode 17b may be formed to have a fine line width.

In the case that the sacrificial layer 13 is an organic layer including a photoresist material, an additional process may be performed in order for the sacrificial layer 13 not to be removed when the photoresist pattern 15 is removed.

Referring to FIG. 2D, a flexible substrate 19 is formed on the substrate 11 having the source electrode 17a and the drain electrode 17b formed thereon to cover the source electrode 17a and the drain electrode 17b.

The forming of the flexible substrate 19 includes coating the sacrificial layer 13 with a soft material solution to completely cover the source electrode 17a and the drain electrode 17b, removing bubbles included in the soft material solution in a vacuum state, and curing the soft material solution. As a result, the source electrode 17a and the drain electrode 17b may be buried in the flexible substrate 19. For example, the soft material solution may be polydimethylsiloxane (PDMS) or polyurethane.

Referring to FIG. 2E, the flexible substrate 19 is formed and the sacrificial layer 13 is then removed.

The sacrificial layer 13 may be removed by performing a wet etching or laser lift-off process. In the case that the sacrificial layer 13 is removed by wet etching, an etching solution able to etch the sacrificial layer 13 may be used. Examples of the etching solution may be hydrofluoric acid (HF), a buffered oxide etch (BOE) solution, ammonia water (NH₃O₄), nitric acid (HNO₃), hydrochloric acid (HCl), or phosphoric acid (H₃PO₄). In the case that the laser lift-off process is performed, the sacrificial layer 13 is irradiated with a laser beam to remove binding energy of an interface between the sacrificial layer 13 and the flexible substrate 19 and thus, a lift-off between the sacrificial layer 13 and the flexible substrate 19 may be performed. For example, an excimer laser may be used to perform the laser lift-off process. The flexible substrate 19 having the source and drain electrodes 17a and 17b buried therein may be formed by removing the sacrificial layer 13.

Since the source electrode 17a and the drain electrode 17b are formed before the flexible substrate 19 is formed, deformation of the flexible substrate 19 may be prevented in comparison to the case that the source electrode 17a and the drain electrode 17b are formed on the flexible substrate 19, and thus, the flexible substrate 19 having improved quality may be formed. In addition, since the source electrode 17a and the drain electrode 17b are formed on the sacrificial layer 13 having low surface roughness, the source electrode 17a and the drain electrode 17b having a flat surface may be formed.

Referring to FIG. 2F, a semiconductor layer 23 is formed on the flexible substrate 19 having top surfaces of the source and drain electrodes 17a and 17b exposed thereon.

The semiconductor layer 23 may be formed on a top surface of the flexible substrate 19 so as to be disposed between the source and drain electrodes 17a and 17b. The semiconductor layer 23 may be formed by chemical vapor deposition, physical vapor deposition, plasma polymerization, or printing. The semiconductor layer 23 may be an organic semiconductor layer, a silicon semiconductor layer, or an oxide semiconductor layer. The organic semiconductor layer may be formed of a polymer material or a low molecular weight material being dissolved in an organic solvent. For example, the organic semiconductor layer may be formed of liquid crystalline polyfluorene block copolymer (LCPBC), pentacene, or polythiophene. The silicon semiconductor layer, for example, may be formed of amorphous silicon. The oxide semiconductor layer may be formed of ZnO-based oxide.

A gate insulating layer 25 may be formed on the flexible substrate 19 to cover the semiconductor layer 23.

The gate insulating layer 25 may be formed of an organic layer (e.g., parylene) or an inorganic layer (e.g., silicon oxide layer (SiO₂) or silicon nitride layer (SiNₓ)).

As illustrated in FIG. 1, a gate electrode 29 may be formed on the gate insulating layer 25. The gate electrode 29 may be formed on the gate insulating layer 25 at the same position as that of the semiconductor layer 23. The gate electrode 29 may be formed by chemical vapor deposition, physical vapor deposition, or atomic layer deposition. The gate electrode 29 may be formed of polysilicon or a metallic material. The metallic material may be copper (Cu), tungsten (W), titanium (Ti), or aluminum (Al).

FIG. 3 is a cross-sectional view illustrating a thin film transistor according to another embodiment of the present invention.

Referring to FIG. 3, in a thin film transistor 200, a gate electrode 49a is buried in a flexible substrate 39. A gate insulating layer 45 may be formed on the flexible substrate 39. A source electrode 37a and a drain electrode 37b spaced apart from each other may be disposed on the gate insulating layer 45. A semiconductor layer 43 may be disposed on the gate insulating layer 45 having the source electrode 37a and the drain electrode 37b spaced apart from each other and exposed thereon.

The gate electrode 49a may be disposed at a center portion of the flexible substrate 39, and a bottom surface and sides of the gate electrode 49a may be buried in the flexible substrate 39. In contrast, a top surface of the gate electrode 49a may be exposed on the flexible substrate 39. The gate insulating layer 45 may be formed to cover the top surface of the flexible substrate 39. As a result, the top surface of the gate electrode 49a may be covered with the gate insulating layer 45.

The source electrode 37a and the drain electrode 37b may be spaced apart from each other and disposed on the gate insulating layer 45. Specifically, each of the source electrode 37a and the drain electrode 37b may be formed on the gate insulating layer 45 so as to be disposed at both sides of a region having the gate electrode 49a formed therein. Portions of the source electrode 37a and the drain electrode 37b may be formed to be superposed with edges of the gate electrode 49a. A top surface of the gate insulating layer 45 may be exposed in a region between the source electrode 37a and the drain electrode 37b.

The semiconductor layer 43 may be formed on the top surface of the gate insulating layer 45 exposed by the source electrode 37a and the drain electrode 37b. Specifically, the semiconductor layer 43 may be formed to cover the exposed top surface of the gate insulating layer 45, and a portion of a top surface of the source electrode 37a and a portion of a top surface of the drain electrode 37b by extending to the top surfaces of the source and drain electrodes 37a and 37b.

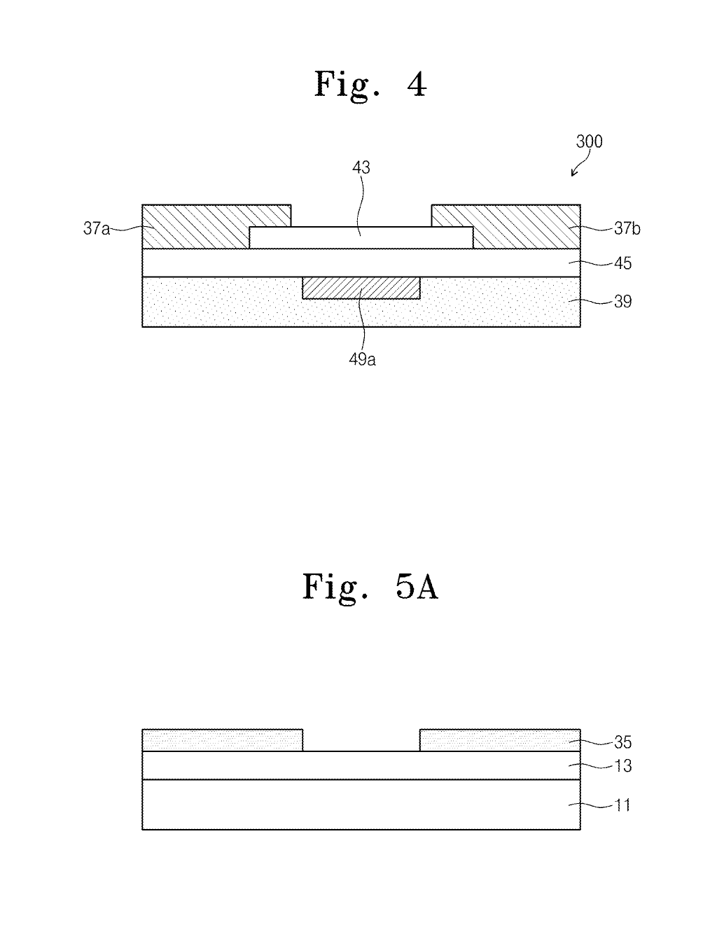

FIG. 4 is a cross-sectional view illustrating a modified example of the thin film transistor in FIG. 3 according to the another embodiment of the present invention. In the another embodiment illustrated in FIG. 4, the same reference numerals are used for the substantially same elements as those of the embodiment and the description related to the corresponding elements will be omitted.

Referring to FIG. 4, in a thin film transistor 300, a semiconductor layer 43 may be disposed on a gate insulating layer 45. The semiconductor layer 43 may be formed on the gate insulating layer 45 so as to be disposed at the same position as that of a gate electrode 49a. Top surfaces of edges of the gate insulating layer 45 may be exposed from the semiconductor layer 43.

A source electrode 37a and a drain electrode 37b may be respectively disposed on the top surfaces of the gate insulating layer 45 exposed from the semiconductor layer 43. The source electrode 37a is formed on one exposed surface of the edge of the gate insulating layer 45 and may be formed to cover an adjacent portion of a top surface of the semiconductor layer 43. The drain electrode 37b is formed on the other exposed surface of the edge of the gate insulating layer 45 and may be formed to cover an adjacent portion of the top surface of the semiconductor layer 43. The source electrode 37a and the drain electrode 37b may be formed on the semiconductor layer 43 so as not to be in contact with each other.

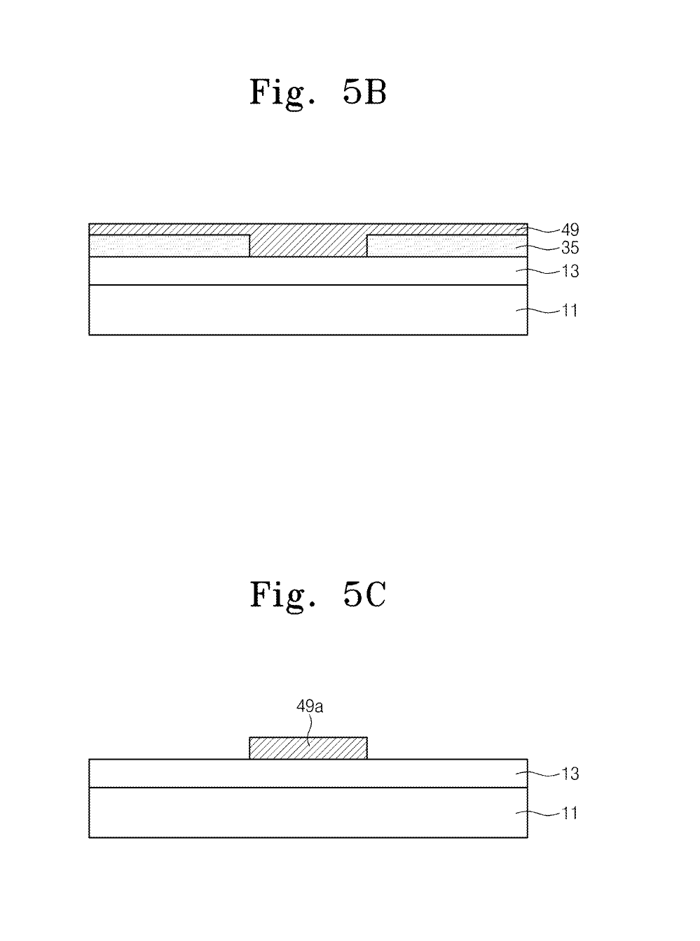

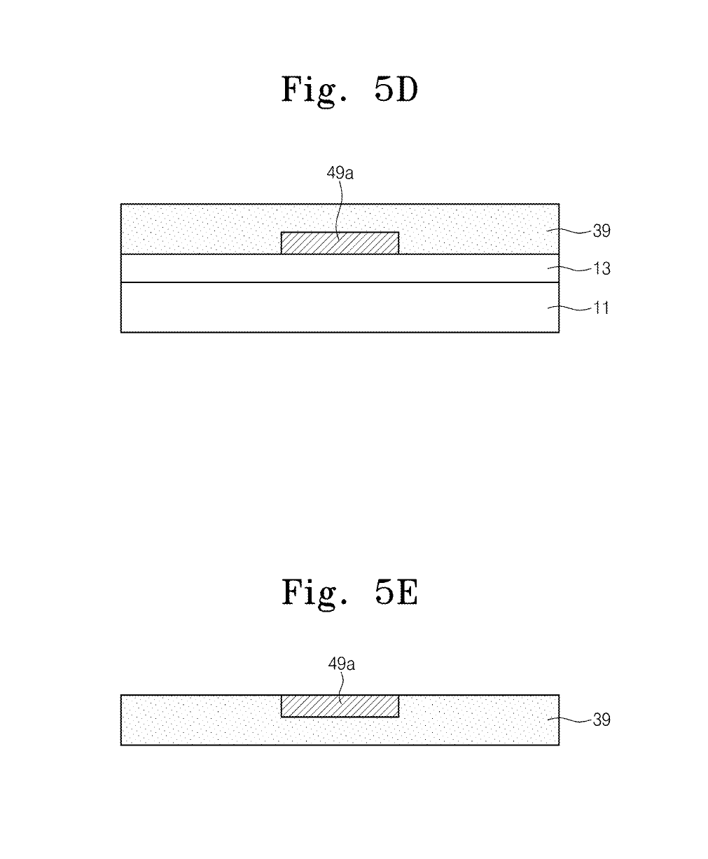

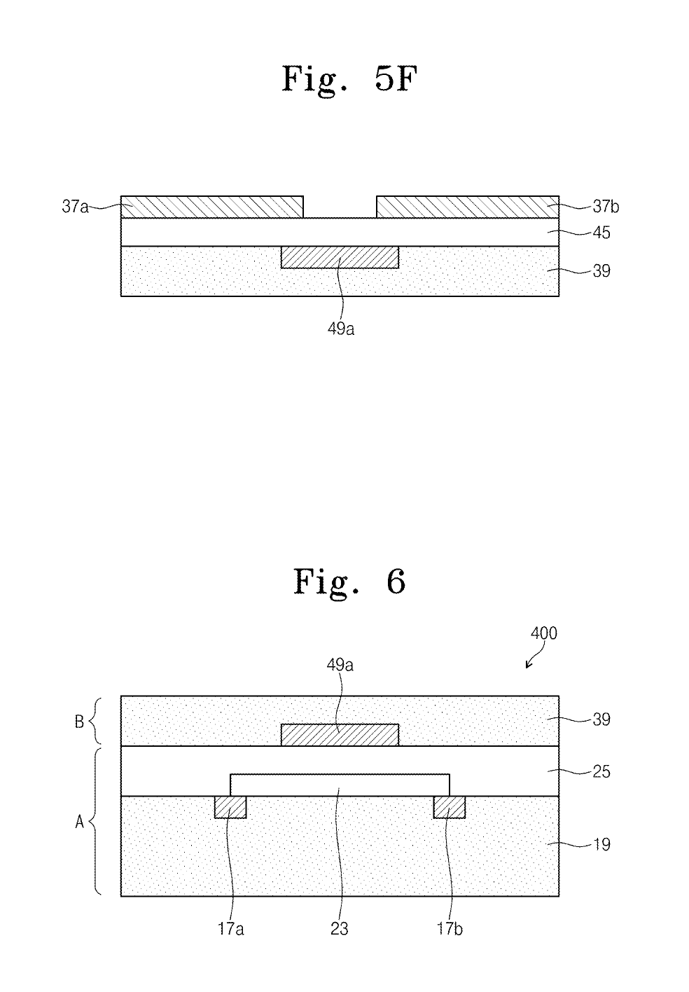

FIGS. 5A through 5F are cross-sectional views illustrating a method of fabricating the thin film transistor according to the another embodiment of the present invention. In the another embodiment illustrated in FIGS. 5A through 5F, the same reference numerals are used for the substantially same elements as those of the embodiment and the description related to the corresponding elements will be omitted.

Referring to FIG. 5A, a substrate 11 is prepared, and a sacrificial layer 13 and a photoresist pattern 35 are formed on the substrate 11.

The substrate 11 may be a glass substrate, a silicon substrate, or a plastic substrate. The sacrificial layer 13 may be a silicon oxide layer (SiO₂), a silicon nitride layer (SiNₓ), an aluminum oxide layer (Al₂O₃), or an organic layer such as a photoresist layer.

The sacrificial layer 13 is formed and the photoresist pattern 35 may be then formed on the sacrificial layer 13 by performing a photolithography process. Specifically, a photoresist layer (not shown) is formed on the sacrificial layer 13 and a photomask pattern (not shown) is then used to etch the photoresist layer exposed through the photomask pattern, and thus, the photoresist pattern 35 may be formed. The photoresist pattern 35 may be formed to expose a portion of a top surface of the sacrificial layer 13. The photoresist pattern 35 may be formed to expose the top surface of the sacrificial layer 13 in a region and the region may be a region in which a gate electrode is formed in a subsequent process.

Referring to FIG. 5B, a gate electrode layer 49 is formed on the photoresist pattern 35.

The gate electrode layer 49 may be formed to completely fill the photoresist pattern 35. The gate electrode layer 49 may be formed by any one of chemical vapor deposition (CVD), physical vapor deposition (PVD), and atomic layer deposition (ALD). The gate electrode layer 49 may be formed of polysilicon or a metallic material. The metallic material may be Cu, W, Ti, or Al.

Referring to FIG. 5C, a gate electrode 49a may be formed on the sacrificial layer 13 by removing the photoresist pattern 35.

Specifically, the photoresist pattern 35 may be removed by performing wet etching by using sulfuric acid (H₂SO₄) and hydrogen peroxide (H₂O₂) as an etching solution. A portion of the gate electrode layer 49 formed above the photoresist pattern 35 may be etched at the same time when the photoresist pattern 35 is etched. Only a portion of the gate electrode layer 49 protected by the photoresist pattern 35 remains and thus, the gate electrode 49a may be formed on the sacrificial layer 13.

Referring to FIG. 5D, a flexible substrate 39 is formed on the sacrificial layer 13 to cover the gate electrode 49a.

The flexible substrate 39 may be formed by coating the sacrificial layer 13 with a soft material solution. For example, the soft material solution may be polydimethylsiloxane (PDMS) or polyurethane.

Referring to FIG. 5E, the flexible substrate 39 is formed and the sacrificial layer 13 is then removed.

The sacrificial layer 13 may be removed by performing a wet etching or laser lift-off process. As a result, the sacrificial layer 13 is removed and thus, the flexible substrate 39 having the gate electrode 49a buried therein may be formed.

Referring to FIG. 5F, a gate insulating layer 45 is formed on the flexible substrate 39 having the gate electrode 49a exposed thereon. The gate insulating layer 45 may be formed of an organic layer (e.g., parylene) or an inorganic layer (e.g., silicon oxide layer (SiO₂) or silicon nitride layer (SiNₓ)).

A source electrode 37a and a drain electrode 37b are formed on the gate insulating layer 45. An electrode layer (not shown) is formed on the gate insulating layer 45 and a mask pattern (not shown) may be formed on the electrode layer so as to expose the electrode layer at a position in which the gate electrode 49a is formed. An exposed portion of the electrode layer is etched by using the mask pattern as an etch mask and thus, the source electrode 37a and the drain electrode 37b spaced apart from each other to expose a portion of a top surface of the gate insulating layer 45 may be formed on the gate insulating layer 45.

As illustrated in FIG. 3, a semiconductor layer 43 may be formed on the source electrode 37a and the drain electrode 37b.

Specifically, the semiconductor layer 43 may be formed to fill the portion of the top surface of the gate insulating layer 45 exposed by the source electrode 37a and the drain electrode 37b being spaced apart from each other and cover portions of top surfaces of the source electrode 37a and the drain electrode 37b. Therefore, top surfaces of edges of the source electrode 37a and the drain electrode 37b may be exposed from the semiconductor layer 43. The semiconductor layer 43 may be an organic semiconductor layer, a silicon semiconductor layer, or an oxide semiconductor layer.

According to another embodiment, referring to FIG. 4, a semiconductor layer 43 may be formed on the gate insulating layer 45 to expose edges of the gate insulating layer 45. The semiconductor layer 43 may be formed on the gate insulating layer 45 so as to be disposed at the same position as that of the gate electrode 49a.

A source electrode 37a and a drain electrode 37b may be respectively formed on edges of the gate insulating layer 45. The source electrode 37a and the drain electrode 37b may be formed to cover a top surface of the gate insulating layer 45 exposed from the semiconductor layer 43 and portions of edges of the semiconductor layer 43.

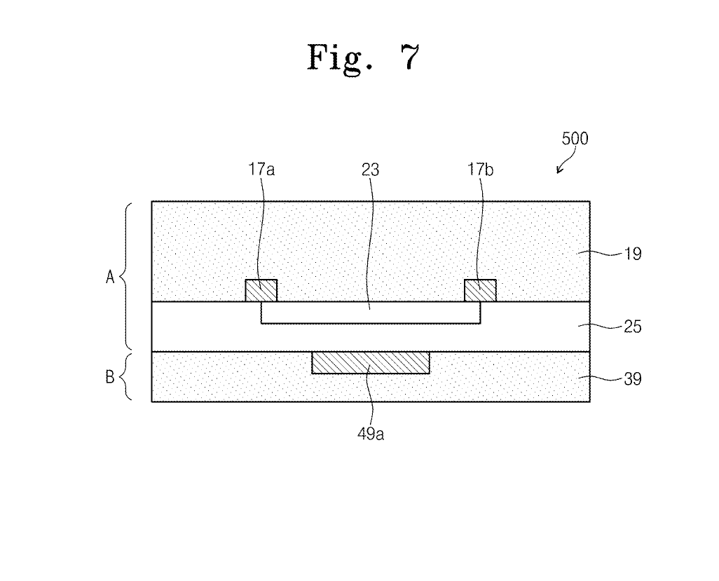

FIG. 6 is a cross-sectional view illustrating a thin film transistor according to another embodiment of the present invention. FIG. 7 is a cross-sectional view illustrating a thin film transistor according to another embodiment of the present invention.

Referring to FIG. 6, a semiconductor substrate A including a semiconductor layer 23 disposed on a flexible substrate 19 having a source electrode 17a and a drain electrode 17b buried therein and a gate insulating layer 25 covering the semiconductor layer 23 has the same structure as that of FIG. 2F, and a gate electrode substrate B including a flexible substrate 39 having the gate electrode 49a buried therein has the same structure as that of FIG. 5E. A thin film transistor 400 having more improved flexibility and stretchability may be formed by bonding the semiconductor substrate A and the gate electrode substrate B.

In the thin film transistor 400, when an interface between the flexible substrate 39 having the gate electrode 49a exposed thereon and the gate insulating layer 25 is coated with an adhesion layer (not shown) and the heat able to melt the adhesion layer is then applied, the semiconductor substrate A and the gate electrode substrate B may be bonded together. In the case that the gate electrode substrate B including the gate electrode 49a is disposed above the semiconductor substrate A including the source electrode 17a and the drain electrode 17b, the thin film transistor 400 may be a top-gate thin film transistor.

Alternatively, as illustrated in FIG. 7, in the case that the gate electrode substrate B including the gate electrode 49a is disposed under the semiconductor substrate A including the source electrode 17a and the drain electrode 17b, a thin film transistor 500 may be a bottom-gate thin film transistor.

With respect to the thin film transistors 400 and 500, since the source and drain electrodes 17a and 17b and the gate electrode 49a are buried in the flexible substrates 19 and 39, stress applied to the channel region due to external stress may be minimized.

The flexible substrate 19 included in the semiconductor substrate A may be formed to have a thickness greater than that of the flexible substrate 39 included in the gate electrode substrate B. The reason for this is that a surface of the semiconductor layer 23 having the channel formed therein must be disposed at the center of the thin film transistor when the semiconductor layer 23 is disposed between the flexible substrates 19 and 39.

With respect to a thin film transistor according to an embodiment of the present invention, a sacrificial layer is formed on a substrate and a flexible substrate is then formed to cover electrodes (e.g., source electrode and drain electrode or gate electrode) on the sacrificial layer. When the sacrificial layer is removed, a flexible substrate having the electrodes buried therein may be formed. The electrodes buried in the flexible substrate may have a flat surface in comparison to electrodes formed on the flexible substrate. Also, since a photolithography process is not performed on the flexible substrate in order to form the electrodes, damage of the flexible substrate may be prevented. Therefore, electrodes buried in the flexible substrate able to have a fine line width formed thereon may be formed.

Also, since a thin film transistor may be formed by using the flexible substrate having the electrodes buried therein, a thin film transistor maintaining electrical properties may be obtained even in the case that the substrate is deformed.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, the preferred embodiments should be considered in descriptive sense only and not for purposes of limitation.

What is claimed is:

1. A thin film transistor comprising:
a source electrode and a drain electrode buried in a first flexible substrate;
a semiconductor layer disposed on the first flexible substrate to be positioned between the source electrode and the drain electrode;
a gate insulating layer completely cover the semiconductor layer; and
a gate electrode facing the semiconductor layer on the gate insulating layer.

2. The thin film transistor of claim 1, wherein the first flexible substrate is formed of PDMS (polydimethylsiloxane) or polyurethane.

3. The thin film transistor of claim 1, wherein a top surface of the first flexible substrate is coplanar with a top surface of the source electrode and a top surface of the drain electrode.

4. The thin film transistor of claim 1, further comprising a second flexible substrate covering the gate electrode on the gate insulating layer.

5. The thin film transistor of claim 4, wherein the first flexible substrate is thicker than the second flexible substrate.

6. A thin film transistor comprising:
a gate electrode buried in a flexible substrate;
a gate insulating layer formed on the flexible substrate;
a source electrode and a drain electrode disposed to be positioned at both sides of the gate electrode on the gate insulating layer; and
a semiconductor layer disposed between the source electrode and the drain electrode.

7. The thin film transistor of claim 6, wherein the semiconductor layer extends to top surfaces of the source electrode and the drain electrode.

8. The thin film transistor of claim 6, wherein the source electrode and the drain electrode are spaced apart to each other and extend to a top surface of the semiconductor layer.

9. A method of fabricating a thin film transistor, the method comprising:
sequentially forming a sacrificial layer on a substrate;
forming one or more metal patterns on the sacrificial layer;
forming a flexible substrate on the sacrificial layer to cover the metal pattern; and
removing the sacrificial layer to form the flexible substrate having the metal pattern buried therein.

10. The method of claim 9, wherein the forming of the metal pattern comprises:
forming a photoresist pattern on the sacrificial layer;
forming a metal layer on the photoresist pattern; and
removing the photoresist pattern by using a lift-off method.

11. The method of claim 9, wherein the forming of the flexible substrate comprises:
coating the sacrificial layer with a soft material solution to completely cover the metal pattern;
removing bubbles included in the soft material solution in a vacuum state; and
curing the soft material solution.

12. The method of claim 11, wherein the soft material solution is PDMS (polydimethylsiloxane) or polyurethane.

13. The method of claim 9, wherein the insulating layer is removed by performing a wet etching or laser lift-off process.

14. The method of claim 9, wherein the metal pattern is a gate electrode.

15. The method of claim 14, further comprising:
forming a gate insulating layer on the flexible substrate having one surface of the gate electrode exposed thereon;
forming a source electrode and a drain electrode on the gate insulating layer to be disposed at both sides of the gate electrode; and
forming a semiconductor layer between the source electrode and the drain electrode.

16. The method of claim 9, wherein the metal patterns are the source electrode and the drain electrode.

17. The method of claim 16, further comprising:
forming a semiconductor layer on the flexible substrate having one surface of the source electrode and the drain electrode exposed thereon;
forming a gate insulating layer on the flexible substrate to be disposed between the source electrode and the drain electrode; and
forming a gate electrode facing the semiconductor layer on the gate insulating layer.
